(19) United States
(12) Patent Application Publication
(10) Pub. No.: US 2022/0208649 A1
(43) Pub. Date: Jun. 30, 2022

(54) SEMICONDUCTOR PACKAGE AND METHOD OF MANUFACTURING THE SAME

(71) Applicant: Samsung Electronics Co., Ltd., Suwon-si (KR)

(72) Inventors: Seungyeol Oh, Seoul (KR); Hyuekjae Lee, Hwaseong-si (KR)

(21) Appl. No.: 17/479,278

(22) Filed: Sep. 20, 2021

(30) Foreign Application Priority Data
Dec. 29, 2020 (KR) 10-2020-0186526

(51) Int. Cl. H01L 23/48; H01L 25/10; H01L 23/498; H01L 23/00; H01L 23/538; H01L 21/768; H01L 21/48

(52) U.S. Cl. CPC H01L 23/481; H01L 2224/08111; H01L 23/49838; H01L 24/94; H01L 23/5386; H01L 24/19; H01L 24/24; H01L 23/5384; H01L 23/49827; H01L 24/08; H01L 21/76898; H01L 21/486; H01L 2225/1023; H01L 2225/1058; H01L 2924/1431; H01L 2924/1434; H01L 2224/24145; H01L 25/105

(57) ABSTRACT

A semiconductor package includes a first semiconductor chip, a second semiconductor chip disposed on the first semiconductor chip and including a through-silicon via electrically connecting a front pad and a rear pad, a dielectric layer having a first region covering a side surface of the second semiconductor chip and a second region filling space between the first semiconductor chip and the second semiconductor chip, a first through-via penetrating through the first region of the dielectric layer, and a second through-via penetrating through the second region of the dielectric layer.

### CROSS-REFERENCE TO RELATED APPLICATION(S)

This application claims the benefit under 35 USC 119(a) of Korean Patent Application No. 10-2020-0186526 filed on Dec. 29, 2020 in the Korean Intellectual Property Office, the entire disclosure of which is incorporated herein by reference for all purposes.

### BACKGROUND

The present inventive concept relates to a semiconductor package and a method of manufacturing the same.

Semiconductor packages installed in electronic devices are required to have high performance and high capacity along with miniaturization. In order to implement the same, a semiconductor package in which semiconductor chips including through-silicon vias (TSVs) are stacked in a vertical direction is being developed.

### SUMMARY

Example embodiments provide a stacked semiconductor package having a bumpless bonding structure with improved production yield, and a method of manufacturing the same.

According to example embodiments, a semiconductor package includes a first semiconductor chip including a first substrate layer, and a first device layer disposed on the first substrate layer and including a plurality of connection pads; a second semiconductor chip including a second substrate layer disposed on the first device layer of the first semiconductor chip and having a first surface and a second surface opposite to the first surface, a front pad disposed on the first surface of the second substrate layer, a rear pad disposed on the second surface of the second substrate layer, and a through-silicon via penetrating through the second substrate layer and electrically connecting the front pad and the rear pad; a dielectric layer having a first region covering a side surface of the second semiconductor chip, and a second region filling space between the first semiconductor chip and the second semiconductor chip; a first through-via penetrating through the first region of the dielectric layer and electrically connected to one of the plurality of connection pads; and a second through-via penetrating through the second region of the dielectric layer and electrically connecting another connection pad to the front pad or the rear pad.

According to example embodiments, a semiconductor package includes a package substrate; a first semiconductor chip disposed on the package substrate, and including a first substrate layer and a first device layer disposed on the first substrate layer and including a plurality of connection pads; and at least one stack structure disposed on the first device layer of the first semiconductor chip. The at least one stack structure includes a second semiconductor chip including a second substrate layer having a first surface and a second surface facing the first device layer and located opposite the first surface, a front pad disposed on the first surface, a rear pad disposed on the second surface, and a through-silicon via penetrating through the second substrate layer and electrically connecting the front pad and the rear pad, a dielectric layer having a first region covering a side surface of the second semiconductor chip and a second region extending from the first region onto the second surface, a first through-via penetrating through the first region of the dielectric layer and electrically connecting one of the plurality of connection pads to the package substrate, and a second through-via penetrating through the second region of the dielectric layer and electrically connecting another connection pad to the rear pad.

According to example embodiments, a method of manufacturing a semiconductor package includes preparing a stacked wafer structure disposed on a carrier wafer and including a plurality of second semiconductor chips spaced apart from each other; preparing a base wafer structure having a plurality of first semiconductor chip units corresponding to the plurality of second semiconductor chips; bonding the stacked wafer structure to the base wafer structure; and removing the carrier wafer. The preparing of the stacked wafer structure includes arranging the plurality of second semiconductor chips on the carrier wafer, forming a dielectric layer on the carrier wafer, the dielectric layer having a first region filling space between the plurality of second semiconductor chips and a second region extending from the first region and respectively covering the plurality of second semiconductor chips, and forming a plurality of first through-vias penetrating through the first region and electrically connected to the plurality of first semiconductor chip units, and a plurality of second through-vias penetrating through the second region and electrically connected to the plurality of second semiconductor chips. The bonding of the stacked wafer structure to the base wafer structure is performed such that the second region of the dielectric layer are respectively disposed between the plurality of first semiconductor chip units and the plurality of second semiconductor chips.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a cross-sectional view illustrating a semiconductor package according to an example embodiment;

FIG. 1B is a plan view illustrating a horizontal cross-section taken along line I-I′ of FIG. 1A.

FIGS. 2A to 2G are cross-sectional views schematically illustrating a method of manufacturing the semiconductor package of FIG. 1A;

FIG. 3 is a cross-sectional view illustrating a semiconductor package according to an example embodiment;

FIGS. 4A and 4B are cross-sectional views illustrating semiconductor packages according to example embodiments, respectively;

FIG. 5 is a diagram illustrating a semiconductor package according to an example embodiment;

FIG. 6 is a diagram illustrating a semiconductor package according to an example embodiment;

FIG. 7 is a diagram illustrating a semiconductor package according to an example embodiment;

FIG. 8 is a perspective view illustrating a wafer structure that may be used to manufacture a semiconductor package according to an example embodiment; and

FIG. 9A is a partially enlarged view illustrating area ‘A’ of FIG. 8, and FIG. 9B is a cross-sectional view illustrating a cross-section taken along line II-II′ of FIG. 9A, and FIG. 9C is a cross-sectional view illustrating a modified example of FIG. 9B that may be employed in an example embodiment of the present inventive concept.

### DETAILED DESCRIPTION

Hereinafter, example embodiments will be described with reference to the accompanying drawings.

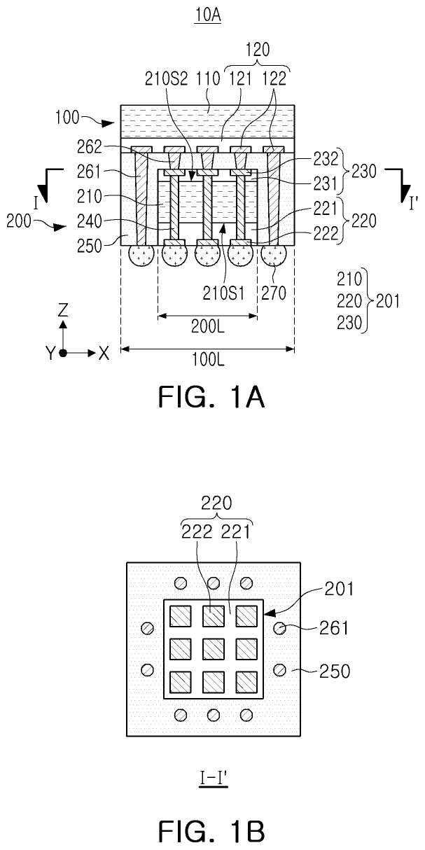

FIG. 1A is a cross-sectional view illustrating a semiconductor package 10A according to an example embodiment, and FIG. 1B is a plan view illustrating a horizon cross-section taken along line I-I′ of FIG. 1A. FIG. 1B illustrates a cross-sectional image of a stack structure 200 along a plane corresponding to the upper surface of a second semiconductor chip 201.

Referring to FIGS. 1A and 1B, a semiconductor package 10A according to an example embodiment may include a first semiconductor chip 100 and at least one stack structure 200. The semiconductor package 10A may further include a connection member 270 disposed below the stack structure 200. The connection member 270 is illustrated in the form of a metal bump (e.g., solder ball), but is not limited thereto, and a conductive member capable of electrically connecting the semiconductor package 10A to an external device or a substrate may be used without limitation. For example, the semiconductor package 10A may include a plurality of connection members disposed at a bottom of the stack structure 200. In an example embodiment, the first semiconductor chip 100 and the stack structure 200 are bonded to each other in a bumpless form, and the stack structure 200 may include components such as a second semiconductor chip 201 and a dielectric layer 250 supporting the same. For example, the first semiconductor chip 100 and the stack structure 200 may be bonded without solder bumps or other types of bumps between them. Accordingly, according to an example embodiment, structural stability of the semiconductor chip structure may be secured and the production yield of the semiconductor package may be improved in an Electrical Die Sorting (EDS) process of a plurality of semiconductor chips (e.g., 100, 201) (hereinafter referred to as ‘semiconductor chip structure’) stacked in a vertical direction (Z-axis direction).

As used herein, components described as being “electrically connected” are configured such that an electrical signal can be transferred from one component to the other (although such electrical signal may be attenuated in strength as it transferred and may be selectively transferred).

The first semiconductor chip 100 may include a first substrate layer 110 and a first device layer 120. The first substrate layer 110 may include a semiconductor substrate, a plurality of conductive regions formed in the semiconductor substrate, and isolation regions on one side of the conductive region. The semiconductor substrate may be a semiconductor wafer. The semiconductor substrate may include a semiconductor element such as silicon or germanium, or a compound semiconductor such as silicon carbide (SiC), gallium arsenide (GaAs), indium arsenide (InAs), and indium phosphide (InP). The conductive region may be, for example, a well doped with impurities or a structure doped with impurities. The isolation region may be a device isolation structure having a shallow trench isolation (STI) structure, and may include silicon oxide.

The first device layer 120 may be disposed on one surface of the first substrate layer 110 and may include an interlayer insulating layer 121 and a plurality of connection pads 122 in the interlayer insulating layer 121. A plurality of devices constituting an integrated circuit (IC) and a circuit structure electrically connected thereto may be included in the interlayer insulating layer 121. The circuit structure may be connected to the plurality of connection pads 122 to interact with an external device. The interlayer insulating layer 121 may surround side surfaces of the plurality of connection pads 122 and expose the bottom surfaces of the plurality of connection pads 122. The interlayer insulating layer 121 may include and/or be formed of an inorganic material capable of participating in physical and/or chemical bonding between the first semiconductor chip 100 and the stack structure 200 in contact with the dielectric layer 250 of the stack structure 200. For example, the interlayer insulating layer 121 may include at least one of silicon oxide and silicon nitride. The plurality of devices may include various microelectronic devices, for example, a metal-oxide-semiconductor field effect transistor (MOSFET), a system large scale integration (LSI), a micro-electro-mechanical system (MEMS), an active device, a passive element, or the like.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

The first semiconductor chip 100 may include and/or may be a logic chip, such as a central processing unit (CPU), a graphics processing unit (GPU), a field programmable gate array (FPGA), a digital signal processing unit (DSP), an image signal processing unit (ISP), an encryption processor, a microprocessor, a microcontroller, an analog-to-digital converter, an application specific semiconductor (ASIC) and the like, a volatile memory chip such as a dynamic random access memory (DRAM) and the like, and/or a nonvolatile memory chip such as PRAM, MRAM, RRAM, a flash memory and the like. In an example embodiment, the type of the first semiconductor chip 100 is not particularly limited, and may include and/or may be a semiconductor chip of the same or different type as the second semiconductor chip 201. However, in an example embodiment, the first semiconductor chip 100 may have a width 100L, e.g., in a first horizontal direction X, greater than a width 200L of the second semiconductor chip 201, e.g., in the first horizontal direction X. Accordingly, a first through-via 261 and the dielectric layer 250 surrounding a side surface of the second semiconductor chip 201 may be disposed on a region of the first semiconductor chip 100 which does not overlap the second semiconductor chip 201 in the vertical direction (Z-axis direction). For example, the first through-via 261 and the dielectric layer 250 may surround the second semiconductor chip 201, e.g., in a plan view. Therefore, structural stability may be obtained even when the first semiconductor chip 100 and the second semiconductor chip 201 are bonded without an adhesive member (e.g., an epoxy adhesive) and a connecting member (e.g., a metal bump).

The stack structure 200 may include the second semiconductor chip 201, the dielectric layer 250, and first and second through-vias 261 and 262. For example, the stack structure 200 may include one or more first through vias 261 and one or more second through vias 262. The second semiconductor chip 201 may be disposed on the first device layer 120 of the first semiconductor chip 100, and may include a second substrate layer 210, a second device layer 220, a protective layer 230, and a through-silicon via 240. Since the second semiconductor chip 201 may include the same or similar technical features as the first semiconductor chip 100 described above, a redundant description will be omitted. For example, the second semiconductor chip 201 may include and/or be formed of the components/elements described above with respect to the first semiconductor chip 100.

The second substrate layer 210 may have a first surface 210S1 and a second surface 210S2 positioned opposite to the first surface 210S1, and may include a semiconductor substrate, a conductive region, and an isolation region. The second device layer 220 may be disposed on the first surface 210S1 of the second substrate layer 210 and may include a front interlayer insulating layer 221 and a front pad 222. A plurality of devices and circuit structures constituting an integrated circuit may be included in the interlayer insulating layer 221. The protective layer 230 may be disposed on the second surface 210S2 of the second substrate layer 210 and may include a rear interlayer insulating layer 231 and a rear pad 232. The through-silicon via 240 may penetrate through the second substrate layer 210 and electrically connect the front pad 222 and the rear pad 232. In the drawing, the through-silicon via 240 penetrates through both the front interlayer insulating layer 221 and the rear interlayer insulating layer 231 to contact the front pad 222 and the rear pad 232, but example embodiments are not limited thereto. In an example, the through-silicon via 240 may be electrically connected to the front pad 222 and the rear pad 232 through a wiring structure in the front interlayer insulating layer 221 or/and the rear interlayer insulating layer 231.

The second semiconductor chip 201 may be disposed in such a manner that the first surface 210S1 or the second surface 210S2 faces the first device layer 120. Accordingly, the second semiconductor chip 201 may be electrically connected to portions of the plurality of connection pads 122 through the front pad 222 or the rear pad 232. In the drawing, the second semiconductor chip 201 is disposed such that the rear pad 232 faces the first device layer 120 of the first semiconductor chip 100, but the configuration is not limited thereto. The second semiconductor chip 201 may be provided with a plurality of front pads 222 and a plurality of rear pads 232 corresponding to each other, and at least a portion of the plurality of front pads 222 and the plurality of rear pads 232 may be used for an Electrical Die Sorting (EDS) process. For example, some of the front pads 222 and the rear pads 232 may be pads for an EDS process. In this case, a pad for the EDS process may be understood as a pad that contacts a probe needle in an electrical test. In an example embodiment, the pad for the EDS process may be one or more of the pads of the second semiconductor chip 201 (e.g., one or more of 222 of FIG. 1A) exposed to one surface (e.g., a lower surface of FIG. 1A) of the semiconductor package 10A after the first semiconductor chip 100 and at least one stack structure 200 are bonded. According to example embodiments, in the bumpless bonding structure of the first semiconductor chip 100 and the second semiconductor chip 201, the second semiconductor chip 201 may be prevented from being shifted. For example, the second semiconductor chip 201 may be protected/supported by the dielectric layer 250.

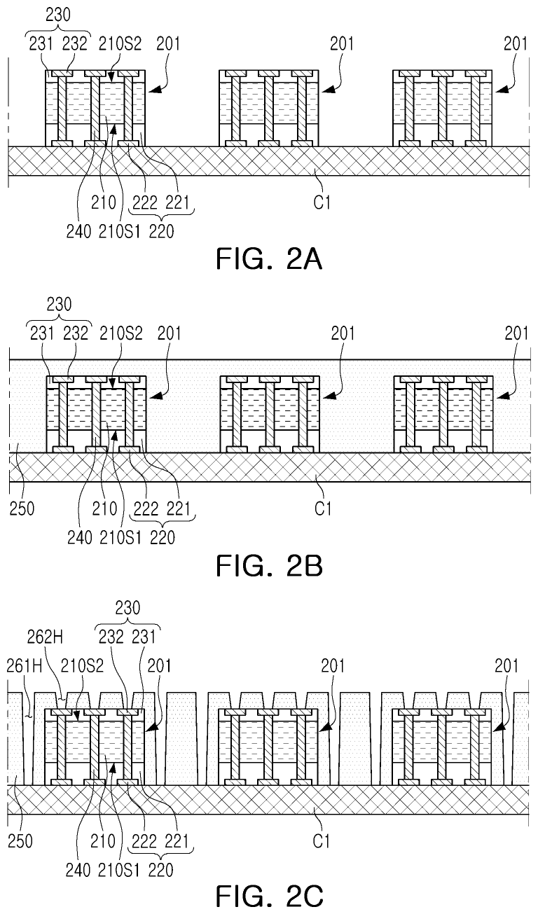

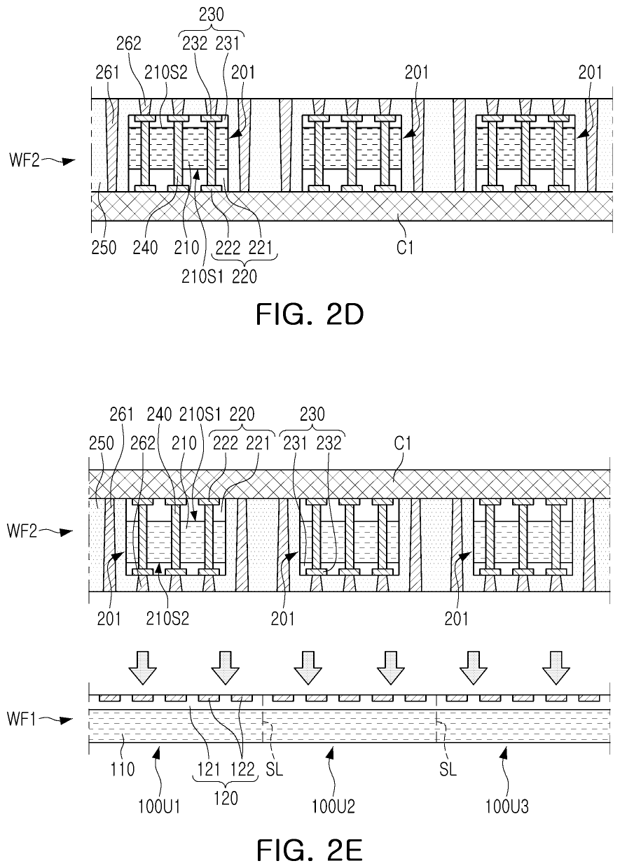

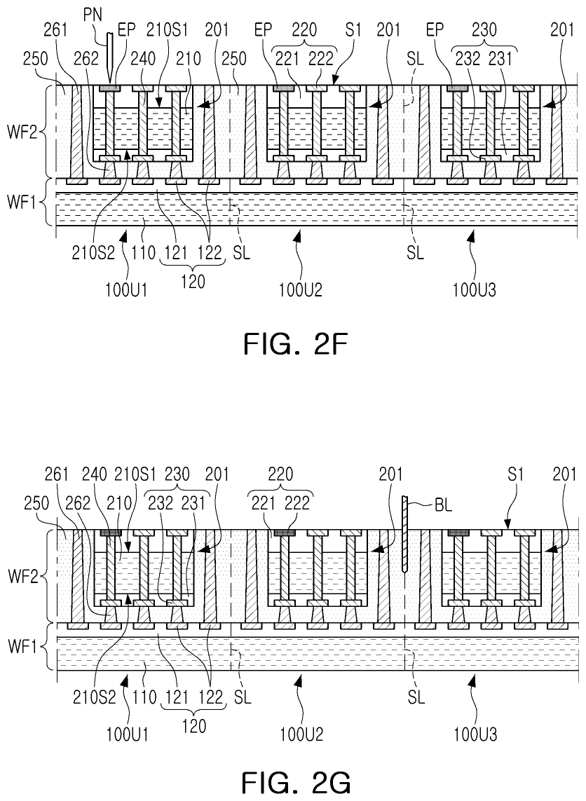

The dielectric layer 250 may include a first region covering a side surface of the second semiconductor chip 201, and a second region extending from the first region onto the second semiconductor chip 201 and filling the space between the first semiconductor chip 100 and the second semiconductor chip 201. For example, the first region of the dielectric layer 250 may not vertically overlap the second semiconductor chip 201, and the second region of the dielectric layer 250 may vertically overlap the second semiconductor chip 201. The dielectric layer 250 may contact the interlayer insulating layer 121 of the first device layer 120 through the second region to participate in surface bonding between the first semiconductor chip 100 and the stack structure 200. Accordingly, the dielectric layer 250, like the interlayer insulating layer 121 of the first device layer 120, may include at least one of silicon oxide and silicon nitride. The dielectric layer 250 may expose one surface (e.g., the lower surface of FIG. 1A) of the second semiconductor chip 201 on which the pad for the EDS process is disposed and may surround the other surfaces, thereby improving structural stability of the semiconductor package 10A. In an example embodiment, the dielectric layer 250 may be bonded to first semiconductor chip units (‘100U1’, ‘100U2’, ‘100U3’ in FIG. 2G) having the form of a base wafer structure (‘WF1’ in FIG. 2G), in the form of a stacked wafer structure (“WF2” in FIG. 2G) including a plurality of second semiconductor chips 201, and may be cut together with the first semiconductor chip units (‘100U1’, ‘100U2’, and ‘100U3’ in FIG. 2G) by a dicing process (see FIG. 2G). Accordingly, the side surface of the dielectric layer 250 may be substantially coplanar with the side surface of the first semiconductor chip 100.

The first and second through-vias 261 and 262 may respectively penetrate through the dielectric layer 250 and are connected to the plurality of connection pads 122 of the first semiconductor chip 100. The first and second through-vias 261 and 262 may include and/or be formed of a metallic material, and may have a side surface tapered such that each width decreases in a direction receding/away from the first semiconductor chip 100. This may be understood as a structural characteristic resulting from the manufacturing process of the present inventive concept in which the wafer-type stack structure 200 and the first semiconductor chip 100 are bonded to each other and handled as a single wafer structure.

The first through-vias 261 may penetrate through the first region of the dielectric layer 250 covering the side surface of the second semiconductor chip 201 and may be connected to some of the plurality of connection pads 122. In this case, the lower surface of the dielectric layer 250, the lower surface of the first through-vias 261, and the lower surface of the front pad 222 may be substantially coplanar with respect to each other. The first through-vias 261 may be disposed to surround the side surface of the second semiconductor chip 201, and in addition to providing an electrical path to the first semiconductor chip 100, the first semiconductor chip 100 and the stack structure 200 may contribute to the structural stability of the bonded semiconductor package.

The second through-vias 262 may penetrate through the second region of the dielectric layer 250 extending onto a top surface of the second semiconductor chip 201 and may electrically connect the remainder of the plurality of connection pads 122 that are not electrically connected to the first through vias 261 to the front pad 222 or the rear pad 232 of the second semiconductor chip 201 facing the first device layer 120. In an example embodiment, the second through-vias 262 may electrically connect the rest of the plurality of connection pads 122 to the rear pad 232 of the second semiconductor chip 201. The second through-vias 262 may have a tapered shape such that the width increases in a direction approaching the plurality of connection pads 122 of the first semiconductor chip 100, thereby securing connection reliability between the rear pads 232 of the second semiconductor chip 201 and the plurality of connection pads 122.

FIGS. 2A to 2G are cross-sectional views schematically illustrating a method of manufacturing the semiconductor package 10A of FIG. 1A. FIGS. 2A to 2G illustrate only a partial region of a wafer structure including a plurality of first semiconductor chips 100 and a plurality of stack structures 200. Hereinafter, the manufacturing process of the stacked wafer structure WF2 including the stack structure 200 of FIG. 1A is first described, but the manufacturing sequence and bonding sequence of the stacked wafer structure WF2 and the base wafer structure WF1 are not limited to the sequence described below.

Referring to FIG. 2A, a method of manufacturing a semiconductor package according to an example embodiment may include preparing a stacked wafer structure including a carrier wafer C1 and a plurality of second semiconductor chips 201 disposed on the carrier wafer C1 and spaced apart from each other. Preparing the stacked wafer structure may include arranging the plurality of second semiconductor chips 201 on the carrier wafer C1, as illustrated in FIG. 2A. The plurality of second semiconductor chips 201 may be known good dies (KGD) selected as good products at the wafer level, and may be bare dies separated by a dicing process. The plurality of second semiconductor chips 201 may be spaced apart by a predetermined distance and may be reconfigured/rearranged on the carrier wafer C1. The plurality of second semiconductor chips 201 may be disposed, such that the first side surface 210S1 faces the carrier wafer C1, but conversely, may be disposed such that the second side surface 210S2 faces the carrier wafer C1.

Referring to FIG. 2B, the preparing the stacked wafer structure may include forming the dielectric layer 250 including a first region filling between the plurality of second semiconductor chips 201 and a second region extending from the first region and covering the upper portions of the plurality of second semiconductor chips 201, on the carrier wafer C1. For example, the first region of the dielectric layer 250 may not vertically overlap the second semiconductor chips 201, and the second region of the dielectric layer 250 may vertically overlap the second semiconductor chips 201. The dielectric layer 250 may be formed by applying and curing an inorganic material such as silicon oxide (e.g., SiO₂) and silicon nitride (e.g., SiCN). The dielectric layer 250 may surround side surfaces of the plurality of second semiconductor chips 201, and may support the plurality of second semiconductor chips 201 so as not to be shifted in a subsequent EDS process. The plurality of second semiconductor chips 201 may include a pad for an EDS process on a surface (a lower surface in FIG. 2B) exposed from the dielectric layer 250. In an example embodiment, each of the plurality of second semiconductor chips 201 may have one surface covered by the dielectric layer 250 (upper surface in FIG. 2B) and another surface (lower surface in FIG. 2B) located opposite to the one surface (upper side in FIG. 2b), and the other surface (lower surface in FIG. 2B) may be exposed from the dielectric layer 250. Accordingly, a portion of the plurality of front pads 222 disposed on the other surface (lower surface in FIG. 2B) of the second semiconductor chip 201 exposed from the dielectric layer 250 may include a pad for the EDS process, to come in contact with the needle for electric test.

Referring to FIG. 2C, the preparing of the stacked wafer structure may include forming a plurality of first via holes 261H penetrating through the first region of the dielectric layer 250 to expose a portion of the carrier wafer C1, and a plurality of second via holes 262H penetrating through the second region of the dielectric layer 250 to expose the rear pads 232 of the plurality of second semiconductor chips 201. The first via holes 261H and the second via holes 262H may be formed by applying a photo resist on the dielectric layer 250 and performing an exposure process, a developing process, and an etching process. The first via holes 261H and the second via holes 262H may have a tapered shape in which a width between inner walls thereof is further reduced in a direction approaching the carrier wafer C1.

Referring to FIG. 2D, the preparing of the stacked wafer structure may include forming the plurality of first through-vias 261 penetrating through the first region of the dielectric layer 250 and contacting the carrier wafer C1, and the plurality of second through-vias 262 penetrating through the second region of the dielectric layer 250 and electrically connected to the plurality of second semiconductor chips 201. The first through-vias 261 and the second through-vias 262 may be formed by a metal layer deposition process, plating process and chemical mechanical polishing (CMP) process. Therefore, the stacked wafer structure WF2 disposed on the carrier wafer C1 may be prepared.

Referring to FIG. 2E, next, the method of manufacturing a semiconductor package according to an example embodiment may include preparing the base wafer structure WF1 having a plurality of first semiconductor chip units 100U1, 100U2, 100U3 corresponding to the plurality of second semiconductor chips 201, and bonding the stacked wafer structure WF2 on the base wafer structure WF1. The base wafer structure WF1 includes a plurality of first semiconductor chip units 100U1, 100U2, and 100U3 that have undergone an EDS process, and the first semiconductor chip units 100U1, 100U2, and 100U3 may include a memory chip or a logic chip. For example, each of the first semiconductor chip units 100U1, 100U2, and 100U3 may be a memory chip or a logic chip. The first semiconductor chip units 100U1, 100U2, and 100U3 may be understood as individual semiconductor chips divided by a scribe line. The bonding of the stacked wafer structure WF2 and the base wafer structure WF1 may be performed such that a plurality of second regions of the dielectric layer 250 is disposed between the plurality of first semiconductor chip units 100U1, 100U2, and 100U3 and the plurality of second semiconductor chips 201. Bonding of the base wafer structure WF1 and the stacked wafer structure WF2 may be performed, first by enabling the interlayer insulating layer 121 of the first device layer 120 and the dielectric layer 250 to contact each other and induce surface bonding therebetween, and then performing a heat treatment process for coupling the plurality of connection pads 122 and the first and second through vias 261 and 262.

Referring to FIG. 2F, after bonding the base wafer structure WF1 and the stacked wafer structure WF2, the carrier wafer C1 is removed to expose the front pads 222 of the plurality of second semiconductor chips 201. In FIG. 2F, one base wafer structure WF1 and one stacked wafer structure WF2 are illustrated, but in an example, a plurality of stacked wafer structures WF2 stacked and bonded in a vertical direction may be bonded onto the base wafer structure WF1. In this case, the front pad 222 of the stacked wafer structure WF2 disposed on the uppermost position may be exposed upwardly.

Subsequently, the EDS process of the semiconductor packages divided by the scribe line SL may be performed. For example, the EDS process may be performed before the semiconductor packages are separated into individual pieces of semiconductor packages. The EDS process may be performed through/using the EDS process pads EP included in the front pads 222 of each of the exposed second semiconductor chips 201. In an example embodiment, since the base wafer structure WF1 and the stacked wafer structure WF2 are bonded through the dielectric layer 250 surrounding the plurality of second semiconductor chips 201, problems such as shifting of the second semiconductor chips 201 caused by contact between a probe needle PN and an EDS process pad EP may be prevented, and production yield may be improved.

Referring to FIG. 2G, the semiconductor package may be individually divided by cutting the base wafer structure WF1 and the stacked wafer structure WF2 along the scribe line SL using a blade BL. By the dicing process, the base wafer structure WF1 may be separated into units to be first semiconductor chips (‘100’ in FIG. 1A), and the stacked wafer structure WF2 may be separated into in units to be stack structures (‘200’ in FIG. 1A), each of which including a second semiconductor chip 201 and at least one first through via 261.

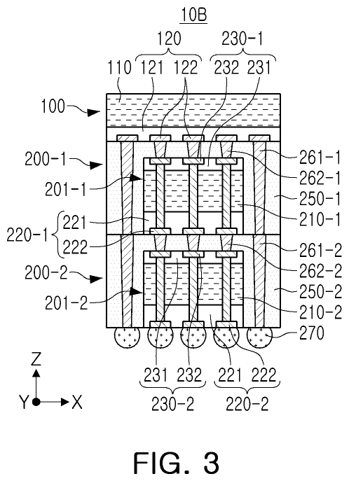

FIG. 3 is a cross-sectional view illustrating a semiconductor package 10B according to an example embodiment.

Referring to FIG. 3, unlike the semiconductor package 10A of FIG. 1A, a semiconductor package 10B according to an example embodiment may have a structure in which a plurality of stack structures 200-1 and 200-2 are bonded. For example, the semiconductor package 10B may include a first semiconductor chip 100, and a first stack structure 200-1 and a second stack structure 200-2 sequentially stacked on the first semiconductor chip 100. Since the first stack structure 200-1 and the second stack structure 200-2 have the same or similar features as the stack structure 200 illustrated in FIG. 1A, overlapping descriptions will be omitted.

The first stack structure 200-1 includes a second semiconductor chip 201-1, a first dielectric layer 250-1, and first and second through-vias 261-1 and 262-1. The second stack structure 200-1 includes a third semiconductor chip 201-2, a second dielectric layer 250-2, and third and fourth through-vias 261-2 and 262-2. The third and fourth through-vias 261-2 and 262-2 may have a shape tapered in the same direction as the first and second through-vias 261-1 and 262-1. The second stack structure 200-2 may be electrically connected to the first stack structure 200-1 and the first semiconductor chip 100 by the third and fourth through-vias 261-2 and 262-2. The third through-via 261-2 may penetrate through the second dielectric layer 250-2 covering the side surface of the third semiconductor chip 201-2 and may be connected to the first through-via 261-1. The fourth through-via 262-2 may penetrate through the second dielectric layer 250-2 covering the upper surface of the third semiconductor chip 201-2 and may be connected to the front pad 222 of the first semiconductor chip 201-1. The upper surface of the third through-via 261-2 and the lower surface of the first through-via 261-1 in contact with each other may have different widths (in the X-axis direction) from each other, and the width of the upper surface of the third through-via 261-2 may be greater than the width of the lower surface of the first through-via 261-1. A connection member 270 may be disposed on the lower surface of the second stack structure 200-2.

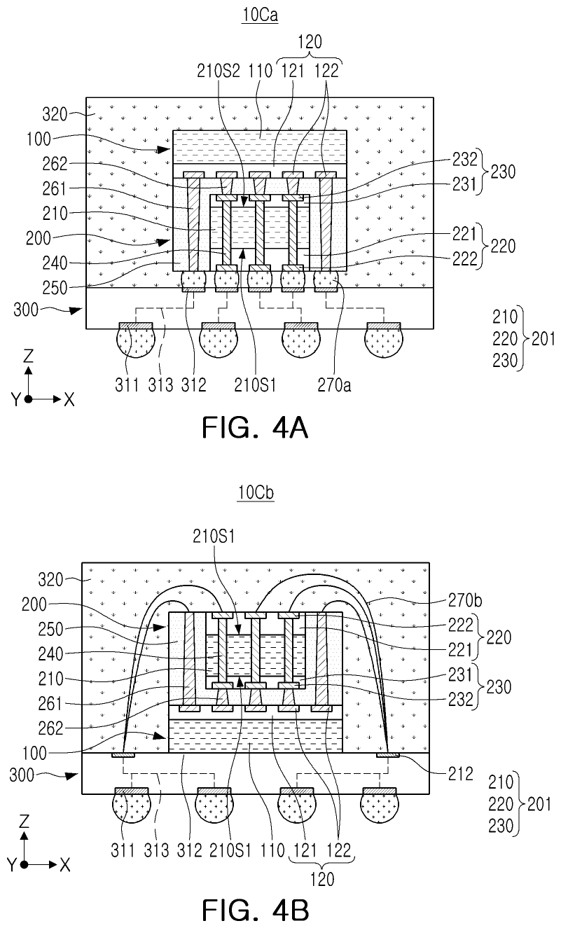

FIGS. 4A and 4B are cross-sectional views illustrating semiconductor packages 10Ca and 10Cb, respectively, according to example embodiments.

Referring to FIG. 4A, the semiconductor package 10Ca according to an example embodiment may have the same or similar characteristics as the semiconductor package 10A of FIG. 1A, except that a package substrate 300 and an encapsulant 320 are further included. The package substrate 300 may include a lower terminal 311 and an upper terminal 312 disposed on a lower surface and an upper surface, respectively, and a connection wiring 313 electrically connecting the lower terminal 311 and the upper terminal 312 to each other. The package substrate 300 may be a substrate for a semiconductor package such as a printed circuit board (PCB), a ceramic substrate, a tape wiring board, and a silicon interposer substrate. The encapsulant 320 may include, for example, a thermosetting resin such as an epoxy resin, a thermoplastic resin such as polyimide, or Ajinomoto Build-up Film (ABF), FR-4, Bismaleimide Triazine (BT), Epoxy Molding Compound (EMC), Photo-imageable Dielectric (PID), or a prepreg including an inorganic filler or/and glass fibers.

In an example embodiment, a first semiconductor chip 100 and a stack structure 200 (hereinafter, referred to as “semiconductor stack structure”) may be mounted on the package substrate 300 in a flip-chip manner. For example, the first semiconductor chip 100 may be disposed in such a manner that a first device layer 120 faces the package substrate 300, and a plurality of connection bumps 270a disposed between the stack structure 200 and the package substrate 300 to electrically connect a first through via 261 and a front pad 222 to the package substrate 300 may be further included. The plurality of connection bumps 270a may include and/or be formed of a metallic material including copper (Cu), aluminum (Al), silver (Ag), tin (Sn), gold (Au), nickel (Ni), lead (Pb), titanium (Ti), or an alloy thereof, and may have a land, ball, or pin structure.

Referring to FIG. 4B, the semiconductor package 10Cb according to an example embodiment may include the same or similar features as the semiconductor package 10Ca of FIG. 4A, except that the semiconductor stack structure is mounted on the package substrate 300 by a wire bonding method. For example, the first semiconductor chip 100 may be disposed such that a first substrate layer 110 faces the package substrate 300, and a connection wire 270b disposed on the stack structure 200 and electrically connecting the first through via 261 and the front pad 222 to the package substrate 300 may be further included.

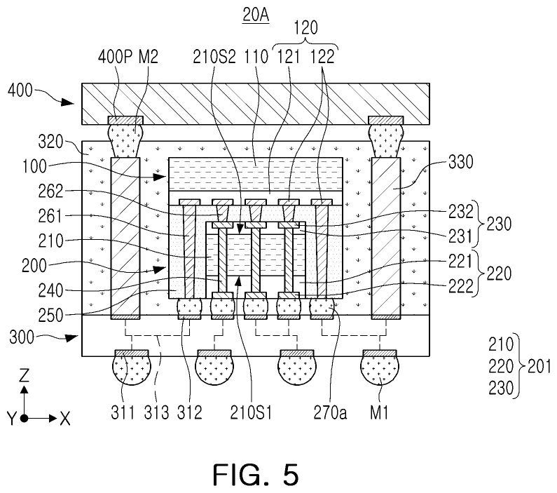

FIG. 5 is a diagram illustrating a semiconductor package 20A according to an example embodiment.

Referring to FIG. 5, a semiconductor package 20A according to an example embodiment may further include a package substrate 300, an encapsulant 320, a vertical connection via 330, and a semiconductor structure 400. The semiconductor package 20A in the example embodiment may have the same or similar characteristics as the semiconductor package 10Ca illustrated in FIG. 4A, except that a semiconductor structure 400 is electrically connected to the package substrate 300 through a vertical connection via 330. The semiconductor structure 400 may be disposed on the encapsulant 320 and may be electrically connected to the vertical connection via 330 through a metal bump M2. The semiconductor structure 400 may be a semiconductor chip including an integrated circuit or a semiconductor package structure including the same. The vertical connection via 330 may be disposed on the package substrate 300, may be electrically connected to the upper terminal 312, and may penetrate through the encapsulant 320 to be connected to the semiconductor structure 400. The vertical connection via 330 may include and/or be formed of, for example, copper (Cu) or a metal material including the same. The semiconductor structure 400 may be electrically connected to the first semiconductor chip 100 and the second semiconductor chip 201 through the vertical connection via 330 and a connection wiring 313. An external connection bump M1 may be connected to a lower terminal 311 and may be disposed below the package substrate 300.

The semiconductor structure 400 may include and/or may be a semiconductor chip of a different type from the first semiconductor chip 100 and the second semiconductor chip 201. For example, the first semiconductor chip 100 and the second semiconductor chip 201 may include and/or may be a volatile memory chip such as DRAM, and/or a nonvolatile memory chip such as PRAM, MRAM, RRAM, a flash memory or the like, and the semiconductor structure 400 may include and/or may be a logic chip such as a central processing unit (CPU), a graphics processing unit (GPU), a field programmable gate array (FPGA), a digital signal processing unit (DSP), an image signal processing unit (ISP), an encryption processor, a microprocessor, a microcontroller, an analog-to-digital converter, an application specific integrated semiconductor (ASIC), or the like.

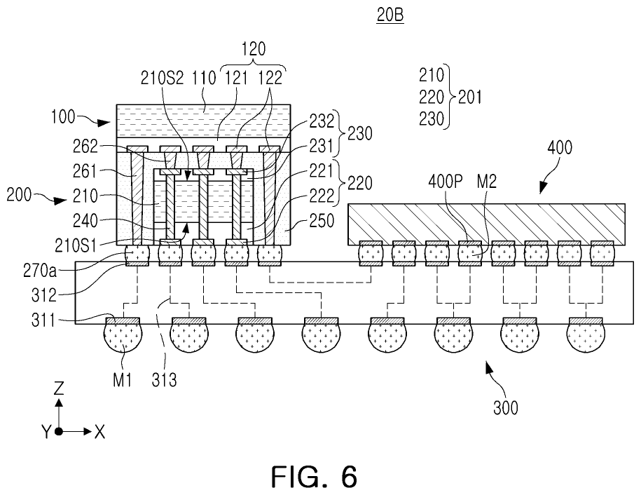

FIG. 6 is a diagram illustrating a semiconductor package 20B according to an example embodiment.

Referring to FIG. 6, the semiconductor package 20B according to an example embodiment may include a semiconductor stack structure including a first semiconductor chip 100 and a stack structure 200 and a semiconductor structure 400 disposed on a package substrate 300. The semiconductor stack structure including the first semiconductor chip 100 and the stack structure 200 may include and or may be at least one of the semiconductor packages of FIGS. 1A to 4B described above. The semiconductor stack structure and the semiconductor structure 400 may be mounted on the package substrate 300 through connection bumps 270a and metal bumps M2, respectively. The package substrate 300 may be, for example, a silicon interposer substrate including Through-Silicon Via (TSV). The connection wiring 313 of the package substrate 300 may electrically connect the semiconductor stack structure and the semiconductor structure 400. The semiconductor stack structure may include a first semiconductor chip 100 and a second semiconductor chip 201 stacked in a vertical direction (Z-axis direction). The first semiconductor chip 100 and the second semiconductor chip 201 may include a memory chip such as DRAM, PRAM, MRAM, RRAM, a flash memory or the like. The semiconductor structure 400 may be a process unit such as a CPU or GPU. The semiconductor structure 400 may be a package of which a normal operation has been verified, for example, a known good package (KGP).

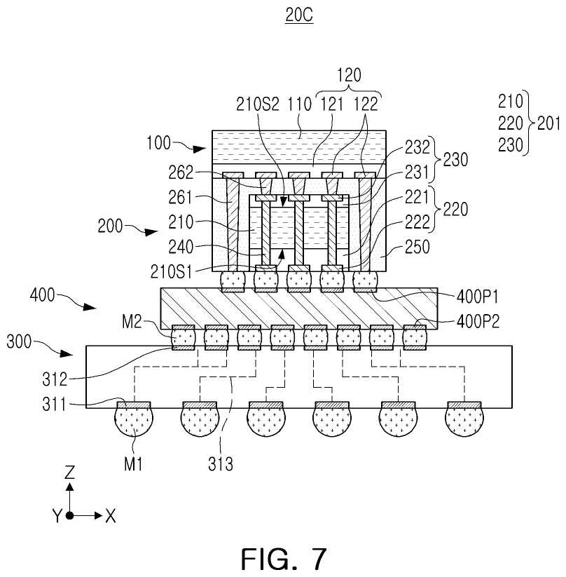

FIG. 7 is a diagram illustrating a semiconductor package 20C according to an example embodiment.

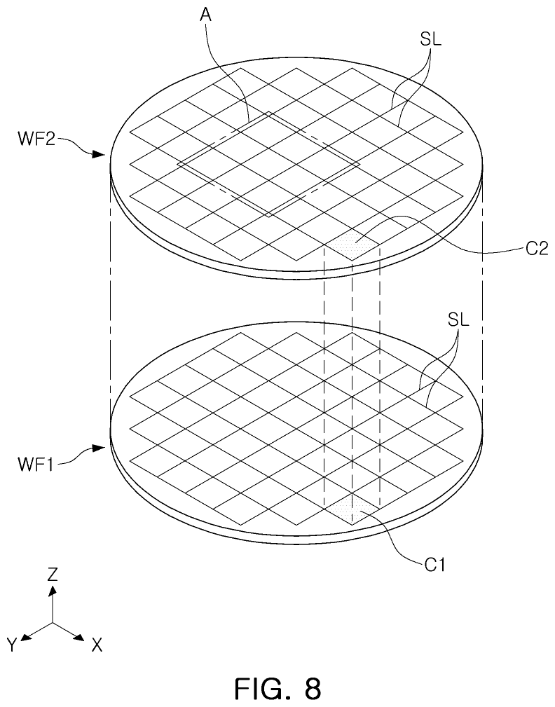

Referring to FIG. 7, a semiconductor package 20C may include a semiconductor structure 400 mounted on a package substrate 300 and a semiconductor stack structure including a first semiconductor chip 100 and a stack structure 200 mounted on the semiconductor structure 400. The semiconductor structure 400 may be electrically connected to the first semiconductor chip 100 and the second semiconductor chip 201 through an upper connection pad 400P1 disposed on the upper surface thereof. The semiconductor structure 400 may further include a TSV electrically connecting the upper connection pad 400P1 and a lower connection pad 400P2. In FIG. 7, components having the same reference numerals as in FIG. 8 have the same or similar features as those described above, and thus overlapping content/descriptions will be omitted.

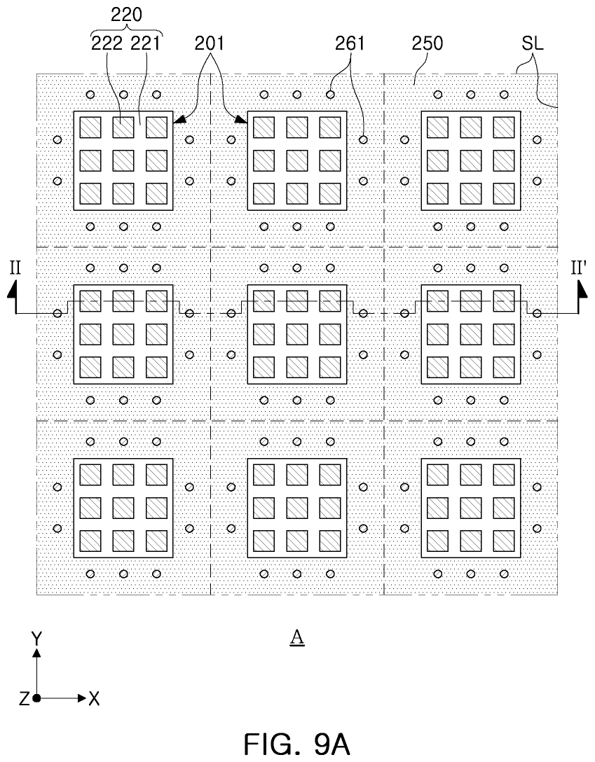

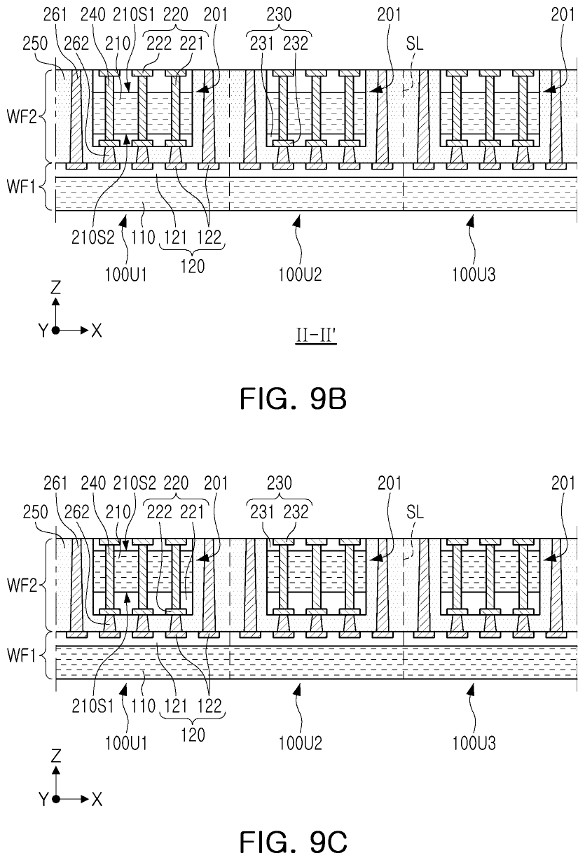

FIG. 8 is a perspective view illustrating a wafer structure that may be used to manufacture a semiconductor package according to example embodiments, FIG. 9A is a partially enlarged view illustrating an area ‘A’ of FIG. 8, and FIG. 9B is a cross-sectional view illustrating a cross section taken along line II-II′ indicated in FIG. 8, and FIG. 9C is a cross-sectional view illustrating a modified example of FIG. 9B that may be employed in an example embodiment.

Referring to FIGS. 8 and 9A, according to an example embodiment of the present inventive concept, a semiconductor package according to various embodiments may be manufactured using a wafer structure in which a base wafer structure WF1 including a plurality of first semiconductor chip regions C1 and a stacked wafer structure WF2 including a plurality of second semiconductor chip regions C2 are bonded together. Although one stacked wafer structure WF2 is illustrated in FIG. 8, a plurality of stacked wafer structures WF2 bonded in a vertical direction (Z-axis direction) may be disposed on the base wafer structure WF1. A plurality of first semiconductor chip regions C1 and a plurality of second semiconductor chip regions C2 correspond to each other, and the plurality of second semiconductor chip regions C2 include the dielectric layer 250, and the first and second through-vias 261 and 262 described above. The wafer structure may be handled as/like a single wafer in that the wafer structure is a single body by surface bonding of the base wafer structure WF1 and the stacked wafer structure WF2.

As illustrated in FIG. 9B, the arrangement direction of the second semiconductor chip 201 in the stacked wafer structure WF2 may be the same as the arrangement direction of the first semiconductor chip units 100U1, 100U2, and 100U3 in the base wafer structure WF1. For example, the first semiconductor chip units 100U1, 100U2, and 100U3 may be disposed in such a manner that the first device layer 120 on which the integrated circuit is formed is located in the first direction. For example, the first device layer 120 may face upward in the base wafer structure WF1, and may be disposed between the first substrate layer 110 and the second semiconductor chip 201. In this case, the second semiconductor chips 201 may also be disposed in such a manner that the second device layer 220 on which the integrated circuit is formed is located in the first direction. For example, the second device layer 220 may face upward in the stacked wafer structure WF2, and may be disposed above the second semiconductor chips 201.

However, as illustrated in FIG. 9C, the arrangement direction of the second semiconductor chip 201 in the stacked wafer structure WF2 may be different from the arrangement direction of the first semiconductor chip units 100U1, 100U2, and 100U3 in the base wafer structure WF1. For example, the first semiconductor chip units 100U1, 100U2, and 100U3 may be disposed such that the first device layer 120 on which the integrated circuit is formed is located in the first direction. In this case, the second semiconductor chips 201 may also be disposed such that the second device layer 220 on which the integrated circuit is formed may be disposed toward the opposite side of the first direction.

As set forth above, according to example embodiments, a semiconductor package having improved production yield and a method of manufacturing the same, by enhancing structural stability in a state in which a plurality of wafer structures stacked in a vertical direction are bumpless bonded, may be provided.

While example embodiments have been illustrated and described above, it will be apparent to those skilled in the art that modifications and variations could be made without departing from the scope of the present inventive concept as defined by the appended claims.

1. A semiconductor package comprising:
a first semiconductor chip including a first substrate layer, and a first device layer disposed on the first substrate layer and including a plurality of connection pads;
a second semiconductor chip disposed on the first device layer of the first semiconductor chip and including a second substrate layer having a first surface and a second surface opposite to the first surface, a front pad disposed on the first surface of the second substrate layer, a rear pad disposed on the second surface of the second substrate layer, and a through-silicon via penetrating through the second substrate layer and electrically connecting the front pad and the rear pad;
a dielectric layer having a first region covering a side surface of the second semiconductor chip, and a second region filling space between the first semiconductor chip and the second semiconductor chip;
a first through-via penetrating through the first region of the dielectric layer and electrically connected to one of the plurality of connection pads; and
a second through-via penetrating through the second region of the dielectric layer and electrically connecting another connection pad to the front pad or the rear pad.

2. The semiconductor package of claim 1, wherein the first semiconductor chip has a width in a first horizontal direction greater than a width of the second semiconductor chip in the first horizontal direction.

3. The semiconductor package of claim 1, wherein a side surface of the first semiconductor chip is substantially coplanar with a side surface of the dielectric layer.

4. The semiconductor package of claim 1, wherein the second semiconductor chip is disposed in such a manner that the rear pad faces the first device layer of the first semiconductor chip.

5. The semiconductor package of claim 4, wherein a lower surface of the dielectric layer, a lower surface of the first through-via, and a lower surface of the front pad are substantially coplanar with respect to each other.

6. The semiconductor package of claim 1, wherein the semiconductor package further comprises a plurality of front pads disposed on the first surface of the second substrate layer and a plurality of rear pads disposed on the second surface of the second substrate layer, and
wherein the plurality of front pads or the plurality of rear pads includes a pad for an electrical die sorting (EDS) process.

7. The semiconductor package of claim 1, wherein the first device layer further includes an interlayer insulating layer that surrounds side surfaces of the plurality of connection pads and contacts the dielectric layer.

8. The semiconductor package of claim 7, wherein the dielectric layer and the interlayer insulating layer include at least one of silicon oxide and silicon nitride.

9. The semiconductor package of claim 1, wherein each of the first through-via and the second through-via has a shape in which a side surface is tapered such that a width decreases in a direction receding from the first semiconductor chip.

10. The semiconductor package of claim 1, further comprising a plurality of connection members disposed on the first through-via, and the front pad or the rear pad.

11. A semiconductor package comprising:
a package substrate;
a first semiconductor chip disposed on the package substrate, and including a first substrate layer and a first device layer disposed on the first substrate layer and including a plurality of connection pads; and
at least one stack structure disposed on the first device layer of the first semiconductor chip,
wherein the at least one stack structure includes,
a second semiconductor chip including a second substrate layer having a first surface and a second surface facing the first device layer and located opposite the first surface, a front pad disposed on the first surface, a rear pad disposed on the second surface, and a through-silicon via penetrating through the second substrate layer and electrically connecting the front pad and the rear pad,
a dielectric layer having a first region covering a side surface of the second semiconductor chip and a second region extending from the first region onto the second surface,
a first through-via penetrating through the first region of the dielectric layer and electrically connecting one of the plurality of connection pads to the package substrate, and
a second through-via penetrating through the second region of the dielectric layer and electrically connecting another connection pad to the rear pad.

12. The semiconductor package of claim 11, further comprising an encapsulant disposed on the package substrate and encapsulating at least a portion of each of the first semiconductor chip and the at least one stack structure.

13. The semiconductor package of claim 11, wherein the first semiconductor chip is disposed in such a manner that the first device layer faces the package substrate, and
the semiconductor package further comprising a plurality of connection bumps disposed between the stack structure and the package substrate and electrically connecting the first through-via and the front pad to the package substrate.

14. The semiconductor package of claim 11, wherein the first semiconductor chip is disposed in such a manner that the first substrate layer faces the package substrate, and
the semiconductor package further comprising a connection wire disposed on the stack structure and electrically connecting the first through-via and the front pad to the package substrate.

15. The semiconductor package of claim 11, wherein the first device layer further includes an interlayer insulating layer surrounding side surfaces of the plurality of connection pads and contacting the dielectric layer.

16. The semiconductor package of claim 15, wherein the dielectric layer and the interlayer insulating layer include at least one of silicon oxide and silicon nitride.

17. The semiconductor package of claim 11, wherein each of the first through-via and the second through-via has a shape in which a side surface is tapered such that a width decreases in a direction receding from the first semiconductor chip.

18-20. (canceled)

21. A semiconductor package comprising:
a first semiconductor chip having a lower surface on which a plurality of first pads is disposed;
a second semiconductor chip, having a front surface on which a front pad is disposed, a rear surface on which a rear pad is disposed, and side surfaces between the front surface and the rear surface, and disposed below the first semiconductor chip so that the front surface or the rear surface faces the lower surface of the first semiconductor chip;
a dielectric layer, disposed between the first semiconductor chip and the second semiconductor chip, and extending on the side surfaces of the second semiconductor chip;
a plurality of connection members disposed below the second semiconductor and the dielectric layer, one of the plurality of connection members electrically connected to the front pad or the rear pad;
a first through-via, extending in a direction perpendicular to the lower surface of first semiconductor chip in the dielectric layer, and electrically connecting one of the plurality of connection pads to another connection member; and
a second through-via, extending in a direction perpendicular to the lower surface of first semiconductor chip in the dielectric layer, and electrically connecting another connection pad to the front pad or the rear pad.

22. The semiconductor package of claim 21, wherein the dielectric layer has a lower surface on which another connection member is disposed, the lower surface of the dielectric layer is coplanar with the front surface or the rear surface.

23. The semiconductor package of claim 21, wherein each of the first through-via and the second through-via has a shape in which a side surface is tapered such that a width decreases in a direction receding from the first semiconductor chip.
